(19) United States
(12) Patent Application Publication
(10) Pub. No.: US 2013/0095294 A1
(43) Pub. Date: Apr. 18, 2013

(54) SILICON CARBIDE INGOT AND SILICON CARBIDE SUBSTRATE, AND METHOD OF MANUFACTURING THE SAME

(71) Applicant: SUMITOMO ELECTRIC INDUSTRIES, LTD., Osaka-shi (JP)

(72) Inventors: Makoto SASAKI, Itami-shi (JP); Shin HARADA, Osaka-shi (JP); Taro NISHIGUCHI, Itami-shi (JP)

(73) Assignee: SUMITOMO ELECTRIC INDUSTRIES, LTD., Osaka-shi (JP)

(21) Appl. No.: 13/653,869

(22) Filed: Oct. 17, 2012

Related U.S. Application Data
(60) Provisional application No. 61/547,799, filed on Oct. 17, 2011.

(30) Foreign Application Priority Data
Oct. 17, 2011 (JP) 2011-227772
Sep. 27, 2012 (JP) 2012-214633

(51) Int. Cl. C30B 23/02; C30B 29/68; C30B 33/00; C30B 29/36

(52) U.S. Cl. CPC C30B 23/025; C30B 29/36; C30B 29/68; C30B 33/00
USPC 428/157; 117/106; 117/105; 428/156; 29/557

(57) ABSTRACT

A silicon carbide ingot excellent in uniformity in characteristics and a silicon carbide substrate obtained by slicing the silicon carbide ingot, and a method of manufacturing the same are obtained. A method of manufacturing a silicon carbide ingot includes the steps of preparing a base substrate having an off angle with respect to a (0001) plane not greater than 1° and composed of single crystal silicon carbide and growing a silicon carbide layer on a surface of the base substrate. In the step of growing a silicon carbide layer, a temperature gradient in a direction of width when viewed in a direction of growth of the silicon carbide layer is set to 10° C./cm or less.

### BACKGROUND OF THE INVENTION

1. Field of the Invention

This invention relates to a silicon carbide ingot and a silicon carbide substrate, and a method of manufacturing the same, and more particularly to a silicon carbide ingot less in variation in such characteristics as impurity concentration and a silicon carbide substrate obtained by slicing the silicon carbide ingot, and a method of manufacturing the same.

2. Description of the Background Art

Silicon carbide (SiC) has conventionally been studied as a next-generation semiconductor material replacing silicon (Si). In order to manufacture a substrate composed of this silicon carbide, a method of manufacturing a substrate by growing a silicon carbide single crystal on a seed substrate to form a silicon carbide ingot and slicing the silicon carbide ingot has conventionally been known. In this case, a method of preparing a seed crystal with a (0001) plane (what is called a c plane) or a crystal plane having an off angle with respect to the c plane not greater than 10° as a growth surface and growing silicon carbide single crystal on the growth surface of the seed crystal is employed (see, for example, Japanese Patent Laying-Open No. 2004-323348 (hereinafter referred to as Patent Literature 1)). In the case where silicon carbide single crystal is grown on such a growth surface of the seed crystal, a (0001) facet plane is formed around a central portion of a surface of grown silicon carbide single crystal.

In Patent Literature 1, in order to prevent formation of heterogeneous polymorphous crystal or different surface orientation crystal and to prevent screw dislocation from being generated, a dislocation control seed crystal having a screw dislocation generation region is prepared and silicon carbide single crystal is grown on the dislocation control seed crystal. In addition, in Patent Literature 1, in the step of growing silicon carbide single crystal, a c-surface facet is formed on the surface of the silicon carbide single crystal, and silicon carbide single crystal is grown such that the (0001) facet plane and the screw dislocation generation region partially overlap with each other. According to Patent Literature 1, by growing silicon carbide single crystal as above, formation of heterogeneous polymorphous crystal or different surface orientation crystal or generation of screw dislocation in the silicon carbide single crystal can be suppressed. In addition, Patent Literature 1 suggests adjustment of a position of the (0001) facet plane such that the (0001) facet plane overlaps with the screw dislocation generation region, with such a method as controlling distribution of concentration of a reaction gas or controlling temperature distribution in seed crystal in the step of growing silicon carbide single crystal.

Here, nitrogen (N) is taken into the (0001) facet plane at the surface of the silicon carbide single crystal described above relatively more readily than into other portions of the surface, during growth of crystal. Therefore, during growth of silicon carbide single crystal described above, a high-nitrogen-concentration region higher in nitrogen concentration than other regions is formed in a portion under the surface where the (0001) facet plane is formed. Since nitrogen concentration in silicon carbide affects such characteristics as conductivity or light transmissivity of silicon carbide single crystal, it is desirably as uniform as possible in an ingot and in a substrate formed from the ingot. In a silicon carbide ingot formed with a conventional method, however, arrangement or a size of the (0001) facet plane was not particularly adjusted in order to obtain an ingot and a substrate uniform in nitrogen concentration. Therefore, in the obtained silicon carbide ingot, a high-nitrogen-concentration region having a size to some extent is formed in the inside of the ingot, although the (0001) facet plane may have been arranged at a position closer to an end portion of the ingot. Thus, in a substrate cut from the ingot, a high-nitrogen-concentration region is arranged in the inside of a region relatively low in nitrogen concentration (that is, a region other than the high-nitrogen-concentration region). Namely, it has conventionally been difficult to form in a silicon carbide substrate, a region uniform in nitrogen concentration, as a sizable region including a substrate central portion.

### SUMMARY OF THE INVENTION

This invention was made to solve the problems as described above, and an object of this invention is to provide a silicon carbide ingot excellent in uniformity in characteristics and a silicon carbide substrate obtained by slicing the silicon carbide ingot, and a method of manufacturing the same.

As a result of the inventor's dedicated studies about growth of silicon carbide crystal, the inventor has completed the present invention. Namely, the inventor has found that, by substantially adopting a (0001) facet plane as a main surface which is a crystal growth surface of a base substrate and making temperature gradient in a radial direction of silicon carbide single crystal gentle during growth of silicon carbide single crystal on a base substrate, an outermost growth surface of the silicon carbide single crystal (that is, a silicon carbide ingot) has a plane orientation substantially the same as that of the main surface (the (0001) facet plane) of the base substrate and consequently the entire surface of a silicon carbide single crystal growth surface can become a facet region. By doing so, silicon carbide single crystal located under the facet region is less in variation in quality, and a most region of the obtained silicon carbide ingot can be formed of homogeneous silicon carbide single crystal. Based on such findings, a method of manufacturing a silicon carbide ingot according to the present invention includes the steps of preparing a base substrate having an off angle with respect to a (0001) plane not greater than 1° and composed of single crystal silicon carbide and growing a silicon carbide layer on a surface of the base substrate. In the step of growing a silicon carbide layer, a temperature gradient in a direction of width when viewed in a direction of growth of the silicon carbide layer is set to 10° C./cm or less. It is noted that a temperature gradient in a direction of width of the ingot is preferably not more than 5° C./cm and more preferably not more than 2° C./cm.

By doing so, since substantially the entire surface including the central portion of an outermost growth surface of the obtained silicon carbide ingot becomes a facet plane, an ingot having the entire surface as the facet plane can be obtained by grinding only an end portion. Therefore, substantially the entire main surface of the silicon carbide substrate cut from the ingot can be the facet plane. Here, if a facet plane and a non-facet plane are both present in a mixed manner in a main surface of a substrate, variation in characteristics may be caused in a device formed on the substrate surface because the facet plane and the non-facet plane are different from each other in nitrogen concentration, condition of generation of dislocation, or the like. Substantially the entire surface of the silicon carbide ingot obtained with the manufacturing method above according to the present invention and the silicon carbide substrate obtained from the ingot, however, is the facet plane, and therefore probability of occurrence of such variation in characteristics can be lowered.

A silicon carbide ingot according to this invention includes a base substrate having an off angle with respect to a (0001) plane not greater than 1° and composed of single crystal silicon carbide and a silicon carbide layer formed on a surface of the base substrate. A surface of the silicon carbide layer located opposite to a side where the base substrate is located includes a (0001) facet plane. The (0001) facet plane includes a central portion of the surface of the silicon carbide layer and extends from the central portion to a position at a distance of 10% of a width of the surface from an outer peripheral end of the surface.

By doing so, since substantially the entire surface (outermost growth surface) including the central portion of the silicon carbide ingot becomes a facet plane, an ingot having the entire surface as the facet plane can be obtained by grinding only an end portion. Therefore, substantially the entire main surface of the silicon carbide substrate cut from the silicon carbide ingot can be the facet plane. Therefore, probability of occurrence of variation in characteristics can be lowered in the silicon carbide ingot obtained with the manufacturing method above according to the present invention and the silicon carbide substrate obtained from the ingot.

The silicon carbide ingot according to this invention is manufactured with the method of manufacturing a silicon carbide ingot above. In this case, since substantially the entire surface including the central portion of an outermost growth surface of the obtained silicon carbide ingot becomes a facet plane, an ingot having the entire surface as the facet plane can be obtained by grinding only an end portion. Therefore, a silicon carbide substrate having substantially the entire main surface as the facet plane can readily be obtained.

A method of manufacturing a silicon carbide substrate according to this invention includes the steps of preparing a silicon carbide ingot with the method of manufacturing a silicon carbide ingot above and slicing the silicon carbide ingot.

In this case, in the silicon carbide ingot, substantially the entire surface including the central portion of the outermost growth surface of the obtained silicon carbide ingot becomes the facet plane. Therefore, by cutting a silicon carbide substrate from the silicon carbide ingot in the slicing step above, a silicon carbide substrate having substantially the entire main surface as the facet plane can readily be obtained.

A silicon carbide substrate according to this invention is manufactured with the method of manufacturing a silicon carbide substrate above. By doing so, a silicon carbide substrate having substantially the entire main surface as the facet plane can readily be obtained.

In the silicon carbide ingot above, a portion located under a region having a (0001) facet plane in the silicon carbide layer may be a high-nitrogen-concentration region higher in nitrogen concentration than a portion other than the portion located under the region having the (0001) facet plane in the silicon carbide layer.

By doing so, the (0001) facet plane which is likely to take in nitrogen is formed on the entire surface of the central portion of the silicon carbide ingot, so that a region relatively high in nitrogen concentration (the high-nitrogen-concentration region located under the (0001) facet plane) can be arranged in the central portion of the silicon carbide ingot. Therefore, the high-nitrogen-concentration region can be formed as a sizable region including the central portion of the silicon carbide ingot. Therefore, in cutting a silicon carbide substrate from the ingot, a silicon carbide substrate in which a high-nitrogen-concentration region is formed in a wide region including a substrate central portion can readily be obtained.

A silicon carbide substrate according to this invention is obtained by slicing the silicon carbide ingot above. By doing so, a silicon carbide substrate in which a region relatively high in nitrogen concentration (or a region where light transmittance is relatively low) is formed in a wide region including a substrate central portion can readily be obtained.

In addition, the silicon carbide substrate according to this invention is obtained by removing a low-nitrogen-concentration region (a region lower in nitrogen concentration than the high-nitrogen-concentration region, which is arranged to surround the high-nitrogen-concentration region) from the silicon carbide ingot above and thereafter slicing the silicon carbide ingot. By doing so, the low-nitrogen-concentration region is removed in advance so that a silicon carbide substrate is formed from the silicon carbide ingot having only the high-nitrogen-concentration region. Therefore, a silicon carbide substrate having reduced fluctuation in characteristics can be obtained.

In the silicon carbide substrate according to this invention, a pattern which is formed by crossing of a straight line along a <11-20> direction and can be observed with X-ray topography is present on at least one main surface.

By doing so, a region where the pattern is present and a region where the pattern is not present on one main surface of the silicon carbide substrate can more readily be distinguished with X-ray topography. Consequently, yield analysis or the like in forming a device on the silicon carbide substrate, in connection with presence/absence of the pattern, is facilitated. It is noted that the straight line forming the pattern includes not only a straight line observed with X-ray topography as a continuous straight line but also such a discontinuous line that a plurality of line segments observed with X-ray topography form a virtual straight line.

In the silicon carbide substrate according to this invention, number density of the pattern present on one main surface above is not less than 0.1/cm² and not more than 1/cm². When number density of the pattern exceeds 1/cm², yield of a device formed on the silicon carbide substrate lowers. On the other hand, when number density of the pattern is less than 0.1/cm², a poly type of the silicon carbide substrate becomes unstable. For such a reason, number density of the pattern present on one main surface above is preferably not less than 0.1/cm² and not more than 1/cm².

In the silicon carbide substrate according to this invention, an area of a circumcircle surrounding the entire pattern present on one main surface above and coming in contact with an outermost portion of at least one pattern is not more than 90% of an area of the entire one main surface above. When the area of the circumcircle above exceeds 90% of the area of the entire one main surface, the patterns are scattered on substantially the entire one main surface, and hence yield of a device formed on the silicon carbide substrate lowers. For such a reason, the area of the circumcircle above is preferably not more than 90% of an area of the entire one main surface above.

According to the present invention, a silicon carbide ingot and a silicon carbide substrate excellent in uniformity in such characteristics as a nitrogen concentration can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart for illustrating a method of manufacturing a silicon carbide ingot according to this invention.

FIG. 2 is a flowchart for illustrating a method of manufacturing a silicon carbide substrate according to this invention.

FIG. 3 is a schematic diagram for illustrating one example of a film formation step shown in FIG. 1.

FIG. 4 is a schematic plan view of the silicon carbide ingot according to the present invention.

FIG. 5 is a schematic cross-sectional view along the line V-V shown in FIG. 4.

FIG. 6 is a schematic plan view showing a silicon carbide substrate cut from the silicon carbide ingot shown in FIGS. 4 and 5.

FIG. 7 is a schematic cross-sectional view of a crystal growth apparatus for performing the film formation step shown in FIG. 1.

FIG. 8 is a schematic plan view showing another example of a silicon carbide substrate according to the present invention.

FIG. 9 is a schematic plan view showing a first variation of the silicon carbide ingot according to this invention.

FIG. 10 is a schematic plan view showing a silicon carbide substrate cut from the silicon carbide ingot shown in FIG. 9.

FIG. 11 is a schematic plan view showing a variation of the silicon carbide substrate shown in FIG. 10.

FIG. 12 is a schematic plan view showing a second variation of the silicon carbide ingot according to this invention.

FIG. 13 is a schematic plan view showing a silicon carbide substrate cut from the silicon carbide ingot shown in FIG. 12.

FIG. 14 is a schematic plan view showing a variation of the silicon carbide substrate shown in FIG. 13.

FIG. 15 is a schematic plan view showing a third variation of the silicon carbide ingot according to this invention.

FIG. 16 is a schematic plan view showing a silicon carbide substrate cut from the silicon carbide ingot shown in FIG. 15.

FIG. 17 is a schematic plan view showing a variation of the silicon carbide substrate shown in FIG. 16.

FIG. 18 is a schematic plan view showing a crossing pattern present on a main surface of the silicon carbide substrate.

FIG. 19 is a photograph of observation with X-ray topography, of the crossing pattern present on the main surface of the silicon carbide substrate.

FIG. 20 is a schematic plan view showing a virtual facet plane on a main surface of the silicon carbide substrate.

### DESCRIPTION OF THE PREFERRED EMBODIMENTS

An embodiment of the present invention will be described hereinafter with reference to the drawings. In the drawings below, the same or corresponding elements have the same reference characters allotted and description thereof will not be repeated.

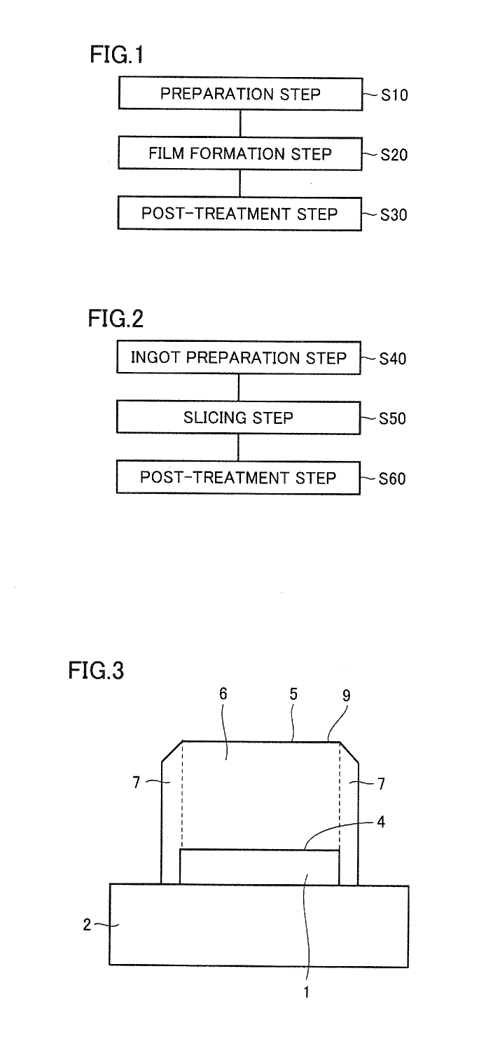

A method of manufacturing a silicon carbide ingot and a silicon carbide substrate according to the present invention will be described with reference to FIGS. 1 to 8.

As shown in FIG. 1, in the method of manufacturing a silicon carbide ingot (hereinafter also referred to as an ingot) according to the present invention, initially, a preparation step (S10) is performed. Specifically, in a treatment vessel of a crystal growth apparatus for forming an ingot, a support member 2 as shown in FIG. 3 is arranged and a base substrate 1 which is a seed substrate for forming an ingot is mounted on support member 2. A two-dimensional shape of base substrate 1 is circular. Here, a main surface of base substrate 1 may have an off angle with respect to a (0001) plane not greater than 1° and more preferably not greater than 0.5°, and more preferably an off angle is 0° (that is, the main surface of base substrate 1 is substantially the (0001) plane).

It is noted that an individual plane orientation is herein denoted as (hkil) and a collective plane orientation including (hkil) and a plane orientation crystal-geometrically equivalent thereto is denoted as {hkil}. In addition, an individual direction is denoted as [hkil] and a direction including [hkil] and a direction crystal-geometrically equivalent thereto is denoted as <hkil>. Moreover, in terms of crystal-geometry, a negative index should generally be denoted by a number with “−” (bar) thereabove, however, a negative sign (−) herein precedes a number.

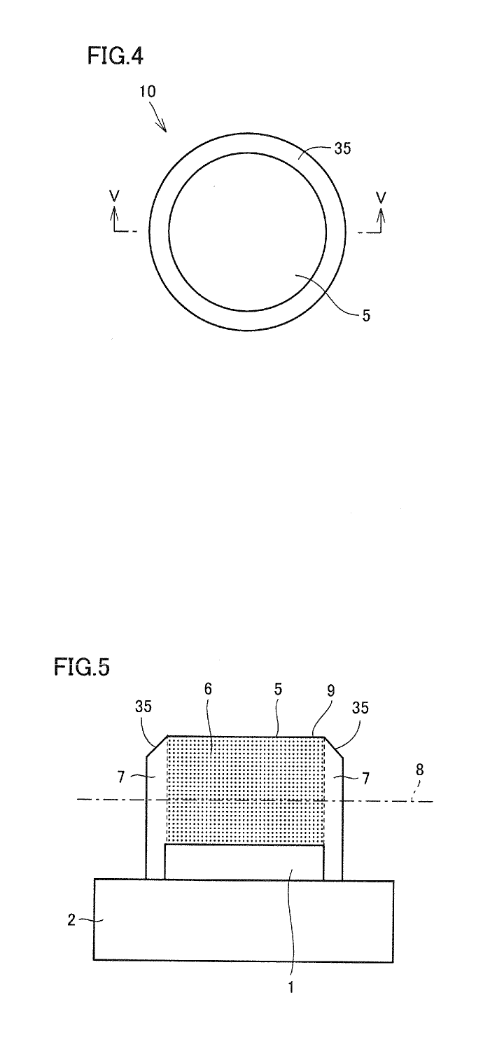

Then, a film formation step (S20) is performed. Specifically, after a pressure and an atmosphere in the treatment vessel in the crystal growth apparatus are set to prescribed conditions, silicon carbide single crystal is grown with a sublimation re-precipitation method or the like on a surface 4 of base substrate 1 while base substrate 1 is heated. Thus, an ingot 10 of silicon carbide as shown in FIGS. 3 to 5 is formed. In addition, in this film formation step (S20), a (0001) facet plane 5 (hereinafter also referred to as a facet plane 5) is formed on a surface of ingot 10. A process condition in the film formation step (S20) is set such that facet plane 5 is formed on substantially the entire upper surface when viewed from above the upper surface of ingot 10 as shown in FIG. 4. It is noted that the process condition will be described later.

In addition, a region continuing under facet plane 5 is a high-nitrogen-concentration region 6 which is relatively higher in nitrogen concentration than other regions (an outer peripheral region of ingot 10) attributed to the fact that an amount of nitrogen taken through facet plane 5 is larger than an amount of nitrogen taken into other regions. Namely, since nitrogen in a relatively larger amount is taken into silicon carbide than in other regions, through facet plane 5 at the surface of gown silicon carbide during growth of silicon carbide forming ingot 10, nitrogen concentration in high-nitrogen-concentration region 6 is relatively higher than nitrogen concentration in a low-nitrogen-concentration region 7 which represents other regions.

As shown in FIG. 4 or 5, this facet plane 5 includes substantially a central portion of the upper surface of ingot 10 and it is arranged on substantially the entire upper surface. Thus, any method can be employed as a method for forming facet plane 5 on substantially the entire upper surface of ingot 10 (process condition). For example, as shown in FIG. 7, such a method that a temperature gradient in a radial direction of ingot 10 is set to 10° C./cm or less in a crystal growth apparatus including a crucible 11 and a heating coil 12 is preferably employed. In this case, an isotherm in ingot 10 extends along the main surface (substantially the (0001) facet plane) of base substrate 1. Consequently, since the outermost growth surface of ingot 10 is the facet plane substantially the same in plane orientation as the main surface of base substrate 1, facet growth more reliably occurs. Namely, by thus making the temperature gradient in the radial direction gentle, a facet region is expanded in the outermost growth surface of ingot 10. Consequently, the entire outermost growth surface of ingot 10 becomes facet plane 5 except for the end portion having a width not more than 10% of a diameter of ingot 10.

In order to set such a temperature gradient, such a method that a heat insulating member such as a carbon felt or a carbon-formed heat insulator is placed in contact with an upper portion of crucible 11 and distribution of an amount of heat leakage from the crucible is minimized to thereby make a temperature condition in the radial direction of ingot 10 in the crucible uniform can be employed.

In addition, as described above, an off angle with respect to the (0001) plane of the main surface (a surface on which crystal to become ingot 10 grows) of base substrate 1 which is a seed substrate is preferably not greater than 1°. By using such a base substrate 1 and forming a film under a temperature condition as above, (0001) facet plane 5 is produced on substantially the entire growth surface of ingot 10 as shown in FIG. 7. Though support member 2 shown in FIG. 3 is not shown in the crystal growth apparatus shown in FIG. 7 but base substrate 1 is arranged directly on an inner wall of crucible 11, support member 2 may be arranged on base substrate 1 as shown in FIG. 3 and base substrate 1 may be fixed onto the inner wall of crucible 11 with support member 2 being interposed.

Here, in order to have the entire outermost growth surface of ingot 10 as (0001) facet plane 5, a temperature at each point of a central portion 24, an end portion 27, and an outermost peripheral portion 16 in the outermost growth surface of ingot 10 shown in FIG. 7 is important. Here, end portion 27 is located in an end region of ingot 10, at a position at a distance within 10% of a diameter of ingot 10 from the inner wall of crucible 11. With a temperature of central portion 24 being denoted as Ta, a temperature of end portion 27 being denoted as Tb, and a temperature of outermost peripheral portion 16 being denoted as Tc, preferably, a relational expression of Tc>Tb≧Ta is satisfied, and temperature Tb and temperature Ta satisfy relation of a temperature gradient ((absolute value of difference between temperature Ta and temperature Tb)/(distance between central portion 24 and end portion 27)) not more than 10° C./cm.

In order to realize such a temperature condition, temperature distribution on a back surface side (that is, an upper surface side of crucible 11 in FIG. 7) of base substrate 1 should be less (variation in temperature should be less). Specifically, for example, such a structure that a heat insulator is arranged on the upper surface of crucible 11 to thereby suppress local divergence of heat from crucible 11 and achieve uniform divergence of heat in an upward direction in the crucible is preferably adopted. Thus, a radius of curvature between central portion 24 and end portion 27 at the surface of ingot 10 can be at least three times as large as a radius of ingot 10. Here, a radius of curvature is calculated, for example, as follows. Initially, a height of ingot 10 (a distance from a surface of base substrate 1 to the surface of ingot 10) is measured at 5-mm pitches between central portion 24 and end portion 27. Then, a radius of an arc corresponding to the surface of ingot 10 at that pitch is calculated based on difference in height at that pitch. Then, a smallest radius of radii of arcs calculated for pitches between central portion 24 and end portion 27 is defined as the radius of curvature above.

In addition, planarity of the surface of ingot 10 may be measured with the following measurement method. Namely, a height of the surface of ingot 10 from a reference surface is measured at a plurality of positions (measurement points) arranged at 5-mm pitches in a direction of cross from the center of the surface of ingot 10 (preferably, in matrix at 5-mm pitches). Then, difference in height between adjacent measurement points is measured. Furthermore, an angle corresponding to inclination of the surface of ingot 10 between the adjacent measurement points is found from a tangent (tan) which can be determined by the difference in height and the distance between the measurement points. An average of a plurality of angles thus found is preferably not greater than 10°. In addition, all measured angles are preferably not greater than 10°. It is noted that a region extending by a distance within 10% of a diameter of ingot 10 from an outermost peripheral portion of ingot 10 is excluded from where measurement points are arranged.

With regard to relation between temperature Tc and temperature Tb, an absolute value of difference between temperature Tb and temperature Tc is preferably not less than 1° C. and not more than 10° C. and more preferably not more than 5° C. (for example, temperature Tc is higher than temperature Tb and difference between temperature Tb and temperature Tc is not more than 10° C. and more preferably not more than 5° C.). Here, in the case where the absolute value of the difference is less than 1° C., polycrystal of silicon carbide is likely to deposit and grow on an inner surface of crucible 11 made of graphite, which results in interference of growth of a single crystal ingot. In the case where the difference is more than 10° C., a temperature of an end surface portion of ingot 10 also increases due to influence by radiant heat or the like from a crucible 11 side. Consequently, temperature difference between central portion 24 and end portion 27 becomes great and it becomes difficult to reliably form a facet plane corresponding to the main surface of base substrate 1 on the outermost growth surface of ingot 10.

As a result of growth under the conditions as above, a surface state of ingot 10 will be the same in plane orientation as the main surface of base substrate 1 and (0001) facet plane 5 is produced on the entire growth surface of ingot 10. In addition, a width of (0001) facet plane 5 is preferably 80% or more of a diameter of ingot 10.

In order to arrange (0001) facet plane 5 on substantially the entire growth surface of ingot 10 as above, such an environment is preferred that temperature distribution is always less in a radial direction of ingot 10 as above from start to end of growth of ingot 10 (such a state that a temperature difference in the radial direction is small). Therefore, attention as below should be paid to temperature control in intermediate and latter periods of growth separately from an early period of growth.

For example, such control that an absolute temperature is changed over time, a temperature difference between an upper portion and a bottom portion of the crucible is varied, or positional relation of a crucible with respect to a furnace body is changed is preferably carried out.

In ingot 10 according to the present invention formed with the method as described above, (0001) facet plane 5 is formed on substantially the entire growth surface of ingot 10. Therefore, probability of generation of dislocation is substantially uniform over the entire surface of ingot 10 and it lowers uniformly with growth of ingot 10. Namely, in ingot 10 according to the present invention, dislocation can be lessened substantially in the entire region.

Then, a post-treatment step (S30) is performed. Specifically, such necessary post-treatment as taking formed ingot 10 out of the treatment vessel, grinding a surface layer, forming a mark indicating a crystal orientation of ingot 10 on ingot 10, and further separating base substrate 1 from ingot 10 is performed.

Here, high-nitrogen-concentration region 6 is formed substantially in the central portion of ingot 10. In addition, nitrogen concentration in high-nitrogen-concentration region 6 is at least 1.1 times as high as nitrogen concentration in low-nitrogen-concentration region 7 located under an outer peripheral portion surface 35 (which is not a facet plane) of ingot 10. It is noted that nitrogen concentration can be evaluated, for example, with SIMS.

Transmittance of light having a wavelength not shorter than 450 nm and not longer than 500 nm per unit thickness in high-nitrogen-concentration region 6 is lower than transmittance of light per unit thickness in low-nitrogen-concentration region 7 which is a portion other than high-nitrogen-concentration region 6 of ingot 10. Transmittance of light can be measured, for example, with FTIR (a Fourier transform infrared spectroscope).

For example, such a method that a thickness of a substrate 20 is set to 400 and transmittance of light having the wavelength above in a direction of thickness of substrate 20 in high-nitrogen-concentration region 6 in substrate 20 and transmittance of light having the wavelength above in the direction of thickness of substrate 20 in low-nitrogen-concentration region 7 in substrate 20 are measured with a visible light spectroscope can be employed.

With such an ingot 10, since high-nitrogen-concentration region 6 relatively high in nitrogen concentration is arranged in a wide range including the central portion of ingot 10, a sizable region including the central portion of ingot 10 can be formed from high-nitrogen-concentration region 6. Therefore, in cutting silicon carbide substrate 20 from ingot 10, silicon carbide substrate 20 where high-nitrogen-concentration region 6 is formed in a wide region including a substrate central portion can readily be obtained.

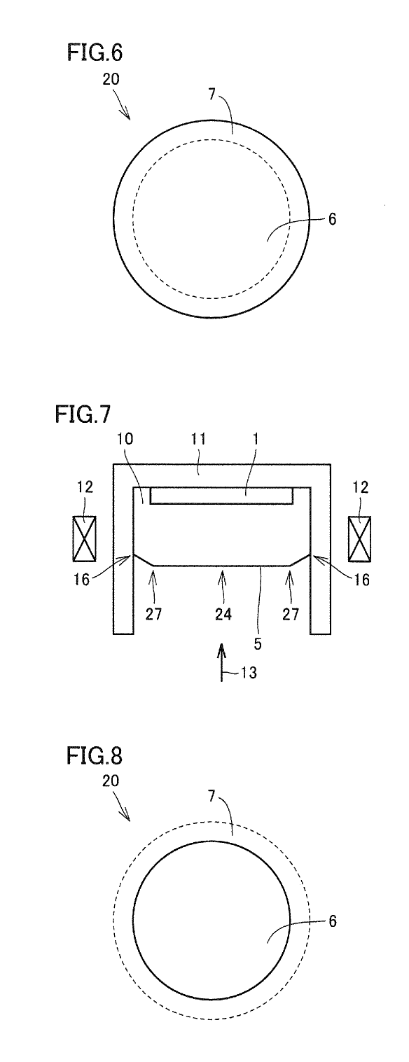

Then, silicon carbide substrate 20 shown in FIG. 6 is manufactured with the use of ingot 10 obtained as described above and the process shown in FIG. 2. A method of manufacturing silicon carbide substrate 20 will be described specifically with reference to FIG. 2.

With the method of manufacturing a silicon carbide substrate according to the present invention, initially, as shown in FIG. 2, an ingot preparation step (S40) is performed. In the step (S40), ingot 10 composed of silicon carbide obtained by performing the step shown in FIG. 1 is prepared.

Then, a slicing step (S50) is performed. Specifically, in the step (S50), ingot 10 is sliced with any method. As a slicing method, for example, a method of using a wire saw, a method of using a cutting member (such as an inner diameter blade) having hard abrasive grains such as diamond arranged on its surface, or the like can be employed. Any direction can be adopted as a direction of slicing of ingot 10, and for example, ingot 10 may be sliced in a direction along surface 4 of base substrate 1 (a direction along a straight line 8 shown in FIG. 5). In this case, high-nitrogen-concentration region 6 can be arranged in a central portion of silicon carbide substrate 20 in cut silicon carbide substrate 20. Alternatively, ingot 10 may be sliced along a plane defined by a direction of an off angle of base substrate 1 and a normal with respect to surface 4 of base substrate 1 (that is, such that a cross-section of ingot 10 shown in FIG. 5 becomes the main surface of silicon carbide substrate 20).

Then, a post-treatment step (S60) is performed. Specifically, finishing to a mirror-smooth state or any surface state is carried out by grinding and polishing a front surface and/or a back surface of a sliced substrate. Silicon carbide substrate 20 as shown in FIG. 6 is thus obtained. In silicon carbide substrate 20, a most part including the central portion of the main surface is high-nitrogen-concentration region 6 and low-nitrogen-concentration region 7 is arranged in the outer peripheral end portion. In addition, as shown in FIG. 8, by removing low-nitrogen-concentration region 7 through grinding or the like, silicon carbide substrate 20 may be in such a state as being formed only from high-nitrogen-concentration region 6. In this case, substantially the entire surface of silicon carbide substrate 20 is high-nitrogen-concentration region 6, and thus silicon carbide substrate 20 uniform in characteristics can be obtained.

According to such a silicon carbide substrate 20, a silicon carbide epitaxial layer excellent in uniformity in characteristics can readily be formed on the surface of silicon carbide substrate 20.

It is noted that, in the post-treatment step (S30) shown in FIG. 1, by performing the method of manufacturing a silicon carbide substrate shown in FIG. 2 after low-nitrogen-concentration region 7 is removed from ingot 10 with such a method as grinding, silicon carbide substrate 20 free from a low-nitrogen-concentration region, that is, having the entire surface as high-nitrogen-concentration region 6, as shown in FIG. 8, can be obtained. Silicon carbide substrate 20 shown in FIG. 8 is basically similar in structure to silicon carbide substrate 20 shown in FIG. 6, however, low-nitrogen-concentration region 7 shown in FIG. 6 has been removed therefrom. Therefore, as the outer peripheral end portion which is a region where low-nitrogen-concentration region 7 has been located is removed from silicon carbide substrate 20 shown in FIG. 8, silicon carbide substrate 20 is smaller in diameter than silicon carbide substrate 20 shown in FIG. 6.

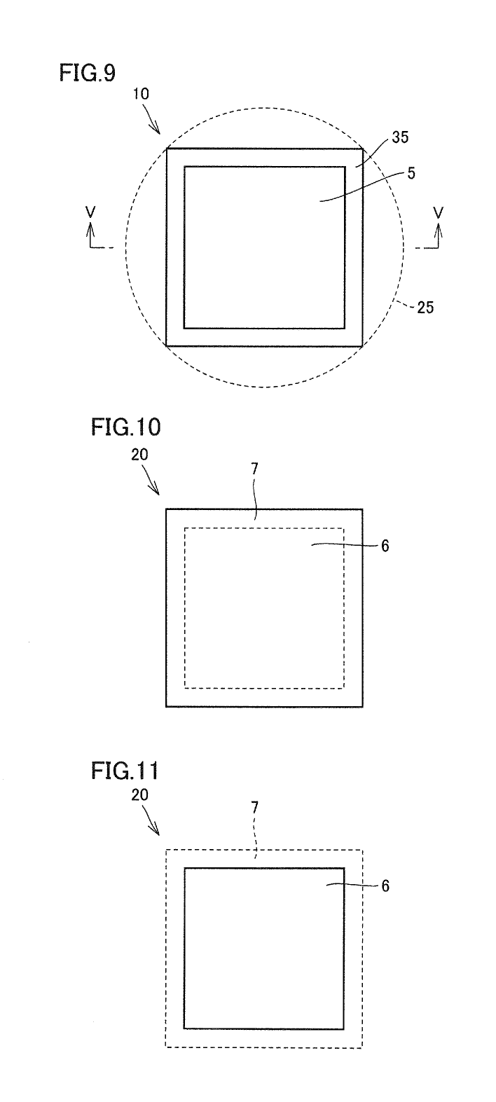

In addition, with the method of manufacturing ingot 10 and silicon carbide substrate 20 described above, a substrate having a circular two-dimensional shape has been employed as base substrate 1, however, a substrate in any other shapes can be employed as base substrate 1. For example, in the case where a substrate having a quadrangle two-dimensional shape is employed as base substrate 1, ingot 10 having a substantially quadrangular two-dimensional shape can be obtained as shown in FIG. 9. In this case as well, by controlling process conditions in the film formation step (S20) shown in FIG. 1, facet plane 5 can be arranged in the central portion when ingot 10 is viewed in a plan view. It is noted that the cross-section along the line V-V in FIG. 9 is similar to the cross-section shown in FIG. 5. Then, a maximum radius of curvature at the outermost surface of obtained ingot 10 (a maximum radius of curvature of an outermost surface 9 in FIG. 5) is preferably at least three times as large as a radius of a circumcircle 25 of the two-dimensional shape of ingot 10 shown in FIG. 9.

Then, in this case as well, by slicing ingot 10 along a direction in parallel to surface 4 of base substrate 1 (that is, a direction shown with straight line 8 in FIG. 5), silicon carbide substrate 20 having a two-dimensional shape as shown in FIG. 10 can be obtained. In silicon carbide substrate 20 shown in FIG. 10 as well, high-nitrogen-concentration region 6 is arranged in the central portion and a region located at the outer peripheral end portion is low-nitrogen-concentration region 7. According to such a silicon carbide substrate 20 as well, an effect similar to that of silicon carbide substrate 20 shown in FIG. 6 can be obtained.

In addition, by removing low-nitrogen-concentration region 7 from silicon carbide substrate 20 shown in FIG. 10 by grinding or the like, silicon carbide substrate 20 having its entire surface as high-nitrogen-concentration region 6 can also be obtained as shown in FIG. 11. It is noted that low-nitrogen-concentration region 7 may be removed in advance from ingot 10 in the step of forming ingot 10 (specifically, in the post-treatment step (S30) shown in FIG. 1). According to such a silicon carbide substrate 20 as well, an effect similar to that of silicon carbide substrate 20 shown in FIG. 8 can be obtained.

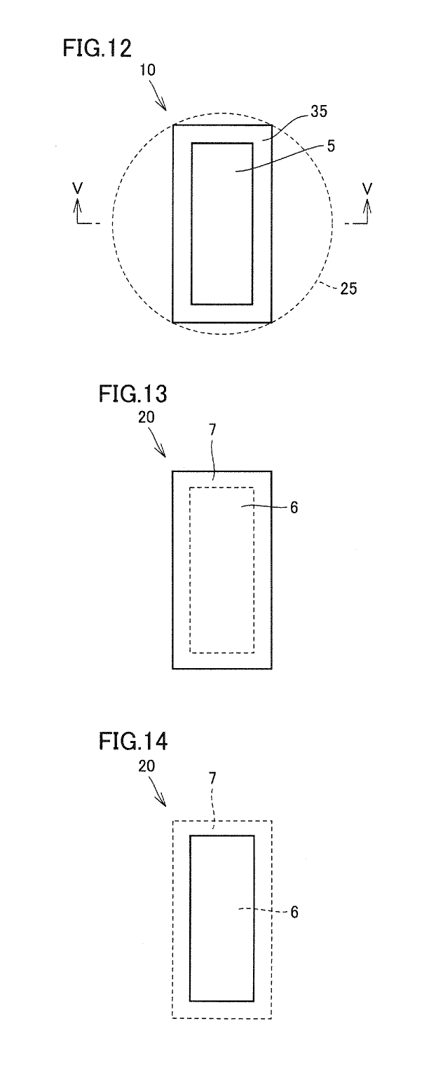

Moreover, a substrate having a rectangular two-dimensional shape as shown in FIG. 12 and composed of silicon carbide single crystal can also be employed as base substrate 1 for forming ingot 10. In this case as well, by using the method of manufacturing an ingot shown in FIG. 1, ingot 10 having a two-dimensional shape as shown in FIG. 12 can be formed. It is noted that the cross-sectional shape of ingot 10 along the line V-V shown in FIG. 12 is basically similar to the cross-sectional shape of ingot 10 shown in FIG. 5. In ingot 10 shown in FIG. 12, a maximum radius of curvature of facet plane 5 (see FIG. 5) which is the outermost surface thereof is preferably at least three times as large as a radius of circumcircle 25 of the two-dimensional shape of ingot 10 shown in FIG. 12.

Then, by slicing ingot 10 shown in FIG. 12 and then subjecting sliced ingot 10 to post-treatment with the method shown in FIG. 2, silicon carbide substrate 20 having a rectangular two-dimensional shape as shown in FIG. 13 can be obtained. It is noted that a direction of slicing is set to a direction in parallel to the sheet surface of FIG. 12 (a direction along the surface of the base substrate). High-nitrogen-concentration region 6 is formed in the central portion also in silicon carbide substrate 20, while a region at the outer peripheral end portion surrounding high-nitrogen-concentration region 6 is low-nitrogen-concentration region 7. According to such a silicon carbide substrate 20 as well, an effect similar to that of the substrate shown in FIG. 6 can be obtained.

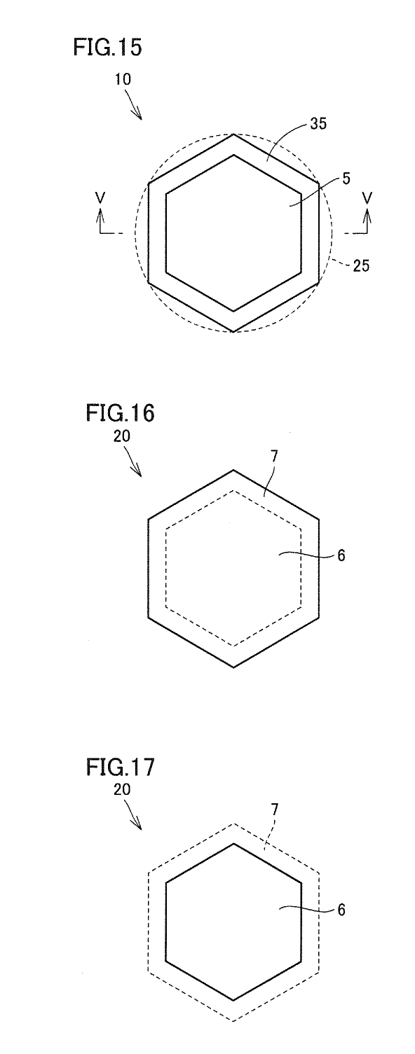

Furthermore, by removing low-nitrogen-concentration region 7 from silicon carbide substrate 20 shown in FIG. 13, silicon carbide substrate 20 having its entire surface as high-nitrogen-concentration region 6 as shown in FIG. 14 can also be obtained. It is noted that, in this case, silicon carbide substrate 20 shown in FIG. 14 may be obtained by removing low-nitrogen-concentration region 7 from ingot 10 at the time of formation of ingot 10 shown in FIG. 12 and thereafter slicing ingot 10.

Alternatively, a substrate having a hexagonal two-dimensional shape can also be employed as base substrate 1. In the case where such a substrate is employed as base substrate 1, ingot 10 having a hexagonal two-dimensional shape as shown in FIG. 15 can be obtained. In such an ingot 10 as well, (0001) facet plane 5 can be arranged in a most part including the central portion of the outermost surface (see FIG. 5) of a crystal growth portion of ingot 10. A two-dimensional shape of (0001) facet plane 5 is similar to a two-dimensional shape of an outer perimeter of ingot 10, and in ingot 10 shown in FIG. 15, (0001) facet plane 5 has a hexagonal two-dimensional shape. It is noted that the cross-sectional view along the line V-V of ingot 10 shown in FIG. 15 is similar to the cross-sectional view shown in FIG. 5. Then, a maximum radius of curvature at the outermost surface of obtained ingot 10 (a maximum radius of curvature of the outermost surface in FIG. 5) is preferably at least three times as large as a radius of circumcircle 25 of the two-dimensional shape of ingot 10 shown in FIG. 15.

Then, by slicing and working ingot 10 shown in FIG. 15 with the method shown in FIG. 2, silicon carbide substrate 20 having a hexagonal two-dimensional shape as shown in FIG. 16 can be obtained. It is noted that a direction of slicing is set to a direction in parallel to the sheet surface of FIG. 15 (a direction along the surface of base substrate 1). Low-nitrogen-concentration region 7 is arranged in the outer peripheral end portion also in silicon carbide substrate 20, while a remaining region including the central portion of silicon carbide substrate 20 is high-nitrogen-concentration region 6. In this case as well, an effect similar to that of the substrate shown in FIG. 6 can be obtained.

In addition, by removing low-nitrogen-concentration region 7 from silicon carbide substrate 20 shown in FIG. 16 by using grinding or the like, silicon carbide substrate 20 having its entire surface as high-nitrogen-concentration region 6 as shown in FIG. 17 can also be obtained. It is noted that, in this case, silicon carbide substrate 20 shown in FIG. 17 may be obtained by removing low-nitrogen-concentration region 7 from ingot 10 at the time of formation of ingot 10 shown in FIG. 15 and thereafter slicing ingot 10.

Here, characteristic features of the present invention will be listed, although they may partially be redundant with those in the embodiment described above.

A method of manufacturing a silicon carbide ingot according to the present invention includes the steps of preparing base substrate 1 having an off angle with respect to a (0001) plane not greater than 1° and composed of single crystal silicon carbide (the preparation step (S10)) and growing a silicon carbide layer on a surface of base substrate 1 (the film formation step (S20)). In the step of growing a silicon carbide layer (the film formation step (S20)), a temperature gradient in a direction of width when viewed in a direction of growth of the silicon carbide layer is set to 10° C./cm or less.

By doing so, the outermost growth surface of obtained silicon carbide ingot 10 has facet plane 5 identical in plane orientation to the main surface of base substrate 1. Namely, substantially the entire surface including the central portion of the outermost growth surface becomes facet plane 5. Therefore, silicon carbide ingot 10 having the entire surface as facet plane 5 can be obtained by grinding only the outer peripheral end portion. Therefore, substantially the entire main surface of silicon carbide substrate 20 cut from silicon carbide ingot 10 can be a facet plane. If such a facet plane and a non-facet plane are both present in a mixed manner in a main surface of silicon carbide substrate 20, variation in characteristics may be caused in a device formed on the surface of silicon carbide substrate 20 because the facet plane and the non-facet plane are different from each other in nitrogen concentration, condition of generation of dislocation, or the like. Substantially the entire surface of silicon carbide ingot 10 obtained with the manufacturing method above according to the present invention and silicon carbide substrate 20 obtained from the ingot, however, is the facet plane, and therefore probability of occurrence of such variation in characteristics can be lowered.

With the method of manufacturing a silicon carbide ingot above, the surface of the silicon carbide layer located opposite to the side where base substrate 1 is located may include (0001) facet plane 5 and (0001) facet plane 5 may include the central portion of the surface of the silicon carbide layer. In addition, in the method of manufacturing a silicon carbide ingot above, (0001) facet plane 5 may extend from the central portion to a position at a distance of 10% of a width of the surface from the outer peripheral end of the surface. Namely, a width of (0001) facet plane 5 may be not less than 80% of the width of the surface.

In this case, at the outermost surface in a direction of growth of obtained silicon carbide ingot 10, a most region including the central portion of the outermost surface can be (0001) facet plane 5. Therefore, silicon carbide substrate 20 obtained from the ingot can have substantially the entire surface as the facet plane.

In the method of manufacturing a silicon carbide ingot above, a portion located under a region having the (0001) facet plane in the silicon carbide layer after the step of growing a silicon carbide layer (the film formation step (S20)) may be high-nitrogen-concentration region 6 higher in nitrogen concentration than a portion other than the portion located under the region having the (0001) facet plane in the silicon carbide layer (low-nitrogen-concentration region 7).

In this case, since high-nitrogen-concentration region 6 is formed under the region having (0001) facet plane 5 and other portions (the outer peripheral portion of silicon carbide ingot 10) are low-nitrogen-concentration region 7 lower in nitrogen concentration than high-nitrogen-concentration region 6, silicon carbide substrate 20 where a wide region including the central portion of the surface is high-nitrogen-concentration region 6 can readily be obtained by slicing silicon carbide ingot 10.

In the method of manufacturing a silicon carbide ingot above, a width of high-nitrogen-concentration region 6 may be not less than 90% of a width of base substrate 1. In this case, since high-nitrogen-concentration region 6 is sufficiently great in size with respect to silicon carbide ingot 10 as a whole, an area occupied by high-nitrogen-concentration region 6 in the surface (main surface) of silicon carbide substrate 20 obtained from silicon carbide ingot 10 can sufficiently be large. Consequently, an area of high-nitrogen-concentration region 6 at the surface of silicon carbide substrate 20 can sufficiently be large. In addition, since low-nitrogen-concentration region 7 located around the outer periphery of high-nitrogen-concentration region 6 can readily be removed in the step of grinding and forming an outer periphery of silicon carbide ingot 10, increase in time required for working of silicon carbide ingot 10 can be suppressed.

The method of manufacturing a silicon carbide ingot above may further include the step of removing a portion other than high-nitrogen-concentration region 6 in the silicon carbide layer (that is, low-nitrogen-concentration region 7) (the post-treatment step (S30) in FIG. 1). In this case, a most part of silicon carbide ingot 10 can be formed from high-nitrogen-concentration region 6. Therefore, since the surface of silicon carbide substrate 20 cut from silicon carbide ingot 10 can be formed only from high-nitrogen-concentration region 6, silicon carbide substrate 20 stable in nitrogen concentration and excellent in homogeneity can be obtained.

In the method of manufacturing a silicon carbide ingot above, transmittance of light having a wavelength not shorter than 450 nm and not longer than 500 nm per unit thickness in high-nitrogen-concentration region 6 may be lower than transmittance of light per unit thickness in a portion other than the high-nitrogen-concentration region (low-nitrogen-concentration region 7) in the silicon carbide layer (the silicon carbide layer grown on base substrate 1).

Here, transmittance of light in silicon carbide ingot 10 tends to lower as nitrogen concentration is higher. Therefore, a value of such a characteristic as transmittance of light above is also different between high-nitrogen-concentration region 6 and a region other than the high-nitrogen-concentration region (low-nitrogen-concentration region 7). Therefore, according to the present invention, since a region where transmittance of light is relatively high (low-nitrogen-concentration region 7) is arranged at the end portion of silicon carbide ingot 10, with regard to such a characteristic as transmittance of light as well, a region relatively low in transmittance of light (high-nitrogen-concentration region 6) can be formed as a sizable region including the central portion of silicon carbide ingot 10. Therefore, in cutting silicon carbide substrate 20 from silicon carbide ingot 10, silicon carbide substrate 20 having substantially uniform transmittance of light in a wide region including the central portion can readily be obtained.

In the method of manufacturing silicon carbide ingot 10 above, micropipe density of a portion located under a region having the (0001) facet plane (high-nitrogen-concentration region 6) may be higher than micropipe density in a portion other than the portion located under the region having the (0001) facet plane in the silicon carbide layer (low-nitrogen-concentration region 7 located under outer peripheral portion surface 35). In this case, since high-nitrogen-concentration region 6 relatively high in micropipe density forms a most part including the central portion of silicon carbide ingot 10, with regard to such a characteristic as micropipe density as well, micropipe density can be made uniform in a sizable region including the central portion of silicon carbide ingot 10. Thus, in cutting silicon carbide substrate 20 from silicon carbide ingot 10, silicon carbide substrate 20 having uniform micropipe density in a wide region including the substrate central portion can readily be obtained.

In the method of manufacturing silicon carbide ingot 10 above, a maximum radius of curvature at the surface of the silicon carbide layer (the outermost surface which is an upper surface of silicon carbide ingot 10 shown in FIG. 5) after the step of growing a silicon carbide layer (the film formation step (S20)) may be at least three times as large as a radius of circumcircle 25 relating to a two-dimensional shape of base substrate 1. In addition, a maximum radius of curvature at the surface of the silicon carbide layer (the outermost surface in FIG. 5) is preferably a maximum radius of curvature at a region including a portion most distant from the surface of base substrate 1 in the silicon carbide layer (the outermost surface).

In this case, since a volume of the silicon carbide layer formed on base substrate 1 can sufficiently be large, a volume of silicon carbide ingot 10 can consequently be sufficiently large. Therefore, in cutting silicon carbide substrate 20 from silicon carbide ingot 10, silicon carbide substrate 20 having a large area can efficiently be obtained. It is noted that the silicon carbide layer may be formed such that a two-dimensional shape of the silicon carbide layer (an epitaxially grown silicon carbide layer made up of high-nitrogen-concentration region 6 and low-nitrogen-concentration region 7) is greater than a two-dimensional shape of base substrate 1 (for example, such that a two-dimensional shape is greater as a distance from base substrate 1 is greater or so as to have a sidewall inclined outward as a distance from base substrate 1 is greater).

Silicon carbide ingot 10 according to this invention is manufactured with the method of manufacturing silicon carbide ingot 10 above. In this case, a region relatively high in nitrogen concentration (high-nitrogen-concentration region 6) can be formed as a sizable region including the central portion of silicon carbide ingot 10. Therefore, by cutting silicon carbide substrate 20 from silicon carbide ingot 10, silicon carbide substrate 20 where high-nitrogen-concentration region 6 relatively high in nitrogen concentration is formed in a wide region including the substrate central portion can readily be obtained.

The method of manufacturing silicon carbide substrate 20 according to this invention includes the steps of preparing a silicon carbide ingot with the use of the method of manufacturing silicon carbide ingot 10 above (the ingot preparation step (S40)) and slicing silicon carbide ingot 10 (the slicing step (S50)) as shown in FIG. 2.

In this case, in silicon carbide ingot 10, a region relatively high in nitrogen concentration (high-nitrogen-concentration region 6) is formed as a sizable region including the central portion of silicon carbide ingot 10. Therefore, by cutting silicon carbide substrate 20 from silicon carbide ingot 10 in the slicing step (S50) above, silicon carbide substrate 20 where high-nitrogen-concentration region 6 relatively high in nitrogen concentration is formed in a wide region including the substrate central portion can readily be obtained.

In the method of manufacturing a silicon carbide substrate above, in the step of preparing a silicon carbide ingot (the ingot preparation step (S40)), a portion located under the region having the (0001) facet plane in the silicon carbide layer after the step of growing a silicon carbide layer (the film formation step (S20)) may be high-nitrogen-concentration region 6 higher in nitrogen concentration than a portion other than the portion located under the region having the (0001) facet plane in the silicon carbide layer (low-nitrogen-concentration region 7). The method of manufacturing a silicon carbide substrate above may further include the step of removing low-nitrogen-concentration region 7 from silicon carbide ingot 10 before the slicing step (S50) of slicing silicon carbide ingot 10 (for example, the step of removing low-nitrogen-concentration region 7 by grinding, which is included in the post-treatment step (S30) in FIG. 1).

From a different point of view, the method of manufacturing silicon carbide substrate 20 according to this invention includes the steps of: preparing a silicon carbide ingot (the ingot preparation step (S40)) with the use of the method of manufacturing silicon carbide ingot 10 as shown in FIG. 2, the surface of the silicon carbide layer located opposite to the side where base substrate 1 is located including (0001) facet plane 5, (0001) facet plane 5 including the central portion of the surface of the silicon carbide layer, in the step of preparing a silicon carbide ingot (the ingot preparation step (S40)), the portion located under the region having (0001) facet plane 5 in the silicon carbide layer after the step of growing a silicon carbide layer (the film formation step (S20)) being high-nitrogen-concentration region 6 higher in nitrogen concentration than a portion other than the portion located under the region having (0001) facet plane 5 in the silicon carbide layer (low-nitrogen-concentration region 7); removing the portion other than high-nitrogen-concentration region 6 (low-nitrogen-concentration region 7) from silicon carbide ingot 10 (for example, the step of removing low-nitrogen-concentration region 7 by grinding, which is included in the post-treatment step (S30) in FIG. 1); and slicing silicon carbide ingot 10 (the slicing step (S50)) after the step of removing the portion other than high-nitrogen-concentration region 6 (low-nitrogen-concentration region 7).

In this case, since a most part of silicon carbide ingot 10 can be high-nitrogen-concentration region 6 by removing low-nitrogen-concentration region 7 located at the outer peripheral portion from silicon carbide ingot 10 from which silicon carbide substrate 20 will be cut, uniformity in nitrogen concentration, transmittance, or the like in silicon carbide ingot 10 can be improved.

Silicon carbide substrate 20 according to this invention is manufactured with the method of manufacturing a silicon carbide substrate above. By doing so, silicon carbide substrate 20 where high-nitrogen-concentration region 6 relatively high in nitrogen concentration is formed in a wide region including the substrate central portion can readily be realized.

The method of manufacturing a silicon carbide ingot according to this invention includes the steps of preparing base substrate 1 having an off angle with respect to a (0001) plane not greater than 1° and composed of single crystal silicon carbide (the preparation step (S10)) and growing a silicon carbide layer on a surface of base substrate 1 (the film formation step (S20)), and in the film formation step (S20), a temperature gradient in a direction of width when viewed in a direction of growth of the silicon carbide layer is set to be not more than 10° C./cm. In the surface of the formed silicon carbide layer, a region having (0001) facet plane 5 in a wide range including the central portion is formed. A portion located under the region having (0001) facet plane 5 (high-nitrogen-concentration region 6) in the silicon carbide layer after the film formation step (S20) is lower in transmittance per unit thickness, of light having a wavelength not shorter than 450 nm and not longer than 500 nm than a portion other than the portion located under the region having (0001) facet plane 5 in the silicon carbide layer (low-nitrogen-concentration region 7).

By doing so, since the region of which transmittance of light has lowered due to nitrogen taken in through (0001) facet plane 5 during growth of the silicon carbide layer (high-nitrogen-concentration region 6) is arranged in a wide range in the central portion of silicon carbide ingot 10 (the portion under (0001) facet plane 5) by forming (0001) facet plane 5 through which nitrogen is likely to be taken in in the central portion of silicon carbide ingot 10, a wide range including the central portion of silicon carbide ingot 10 can be a region uniform in transmittance of light. Therefore, when silicon carbide substrate 20 is cut from silicon carbide ingot 10, silicon carbide substrate 20 where a region relatively uniform in transmittance of light (high-nitrogen-concentration region 6) is formed in a wide region including the substrate central portion can readily be obtained. Since transmittance of light can thus substantially be uniform in a wide region including the substrate central portion, a semiconductor element can efficiently be formed in forming a semiconductor element on the substrate surface.

Silicon carbide ingot 10 according to this invention includes base substrate 1 having an off angle with respect to the (0001) plane not greater than 1° and composed of single crystal silicon carbide and a silicon carbide layer formed on the surface of base substrate 1. The surface of the silicon carbide layer located opposite to the side where base substrate 1 is located includes (0001) facet plane 5. The (0001) facet plane 5 includes the central portion of the surface of the silicon carbide layer and extends to a position at a distance of 10% of a width of the surface from the outer peripheral end of the surface.

In silicon carbide ingot 10 above, the portion located under the region having (0001) facet plane 5 in the silicon carbide layer may be high-nitrogen-concentration region 6 higher in nitrogen concentration than a portion other than the portion located under the region having the (0001) facet plane in the silicon carbide layer (low-nitrogen-concentration region 7).

By doing so, since substantially the entire surface including the central portion of the surface (the outermost growth surface) of silicon carbide ingot 10 becomes the facet plane, silicon carbide ingot 10 having the entire surface as the facet plane can be obtained by grinding only the end portion. Therefore, substantially the entire main surface of silicon carbide substrate 20 cut from silicon carbide ingot 10 can be the facet plane. Therefore, in silicon carbide ingot 10 obtained with the manufacturing method above according to the present invention and silicon carbide substrate 20 obtained from silicon carbide ingot 10, probability of occurrence of variation in characteristics can be lowered.

In silicon carbide ingot 10 above, nitrogen concentration in high-nitrogen-concentration region 6 may be at least 1.1 times as high as nitrogen concentration in the portion other than the portion located under the region having (0001) facet plane 5 (low-nitrogen-concentration region 7).

In this case, high-nitrogen-concentration region 6 and low-nitrogen-concentration region 7 can readily be distinguished from each other based on a nitrogen concentration, a transmittance of light, or the like. Therefore, such an operation as removal of low-nitrogen-concentration region 7 from silicon carbide ingot 10 by grinding, or cutting of silicon carbide substrate 20 from silicon carbide ingot 10 and formation of a device in a manner avoiding low-nitrogen-concentration region 7 in forming the device on the surface of silicon carbide substrate 20 (or in a manner not extending over a boundary portion between high-nitrogen-concentration region 6 and low-nitrogen-concentration region 7) can readily be performed.

In silicon carbide ingot 10 above, a width of high-nitrogen-concentration region 6 may be not less than 80% and more preferably not less than 90% of a width of base substrate 1. In this case, a sufficiently large size of high-nitrogen-concentration region 6 can be ensured.

It is noted that, in silicon carbide ingot 10 above, transmittance of light having a wavelength not shorter than 450 nm and not longer than 500 nm per unit thickness in high-nitrogen-concentration region 6 may be lower than transmittance of light per unit thickness in the portion other than the high-nitrogen-concentration region in the silicon carbide layer (low-nitrogen-concentration region 7).

In this case, high-nitrogen-concentration region 6 and low-nitrogen-concentration region 7 can readily be distinguished from each other based on a transmittance of light. Therefore, such an operation as removal of low-nitrogen-concentration region 7 from silicon carbide ingot 10 by grinding can readily be performed.

In silicon carbide ingot 10 above, transmittance in high-nitrogen-concentration region 6 may be lower by at least 5% than transmittance in low-nitrogen-concentration region 7 which is the portion other than the high-nitrogen-concentration region in the silicon carbide layer. In this case, high-nitrogen-concentration region 6 and low-nitrogen-concentration region 7 can readily be distinguished from each other based on difference in transmittance.

In silicon carbide ingot 10 above, micropipe density in the portion located under the region having the (0001) facet plane (high-nitrogen-concentration region 6) may be higher than micropipe density in the portion other than the portion located under the region having (0001) facet plane 5 in the silicon carbide layer (low-nitrogen-concentration region 7). In this case, the portion located under the region having (0001) facet plane 5 (high-nitrogen-concentration region 6 which is a portion substantially uniform and relatively high in micropipe density) is formed as a sizable region including the central portion of silicon carbide ingot 10. Therefore, when silicon carbide substrate 20 is cut from ingot 10, silicon carbide substrate 20 where a region relatively uniform in micropipe density is formed in a wide region including the substrate central portion can readily be obtained.

In silicon carbide ingot 10 above, micropipe density in the portion located under the region having (0001) facet plane 5 (high-nitrogen-concentration region 6) may be at least 1.2 times as high as micropipe density in the portion other than the portion located under the region having (0001) facet plane 5 in the silicon carbide layer (low-nitrogen-concentration region 7). In this case, high-nitrogen-concentration region 6 and low-nitrogen-concentration region 7 can readily be distinguished from each other.

In silicon carbide ingot 10 above, a maximum radius of curvature at the surface of the silicon carbide layer (the outermost surface where (0001) facet plane 5 is formed in silicon carbide ingot 10 shown in FIG. 5) may be at least 3 times as large as a radius of circumcircle 25 relating to a two-dimensional shape of base substrate 1. In this case, since a volume of the silicon carbide layer formed on base substrate 1 can sufficiently be large, a volume of silicon carbide ingot 10 can consequently be sufficiently large.

Silicon carbide substrate 20 according to this invention is obtained by slicing silicon carbide ingot 10 above. By doing so, silicon carbide substrate 20 where high-nitrogen-concentration region 6 relatively high in nitrogen concentration (or a region lower in transmittance of light) is formed in a wide region including the substrate central portion can readily be obtained.

Silicon carbide substrate 20 according to this invention may be obtained by removing the region other than high-nitrogen-concentration region 6 (low-nitrogen-concentration region 7) from silicon carbide ingot 10 and thereafter slicing silicon carbide ingot 10. By doing so, silicon carbide substrate 20 is fanned with the use of silicon carbide ingot 10 in which high-nitrogen-concentration region 6 (a region lower in transmittance of light than the low-nitrogen-concentration region) occupies a most part (or formed only from high-nitrogen-concentration region 6) as a result of removal in advance of low-nitrogen-concentration region 7. Therefore, silicon carbide substrate 20 where fluctuation in nitrogen concentration or transmittance of light has been lessened can be obtained.

In silicon carbide substrate 20 shown in FIGS. 8, 11, 14, 17, and the like, variation from an average value of nitrogen concentration may be not more than 10%. In this case, since variation in nitrogen concentration is sufficiently less to such an extent as not adversely affecting characteristics of silicon carbide substrate 20, silicon carbide substrate 20 uniform in characteristics can reliably be obtained.

In silicon carbide substrate 20 above, variation from an average value of dislocation density may be not more than 80%. In addition, variation from an average value of dislocation density in high-nitrogen-concentration region 6 may be not more than 80%. In this case, with variation in dislocation density as above, variation in characteristics in the main surface of silicon carbide substrate 20 can be suppressed to such an extent that no practical problem arises.

A size of silicon carbide substrate 20 above (for example, a maximum width when viewed two-dimensionally) may be not smaller than 4 inches. If the present invention is applied to silicon carbide substrate 20 having a size not smaller than 4 inches, a significant effect in particular in terms of efficiency in manufacturing a device can be obtained.

In silicon carbide substrate 20 above, nitrogen concentration in high-nitrogen-concentration region 6 may be at least 1.1 times as high as nitrogen concentration in other portions (low-nitrogen-concentration region 7). In this case, high-nitrogen-concentration region 6 and the portion other than the high-nitrogen-concentration region (low-nitrogen-concentration region 7) can readily be distinguished from each other based on a transmittance of light or the like.

In addition, in silicon carbide substrate 20 above, a width of high-nitrogen-concentration region 6 may be not less than 80% and more preferably not less than 90% of a width of silicon carbide substrate 20. In this case, a sufficiently large size of high-nitrogen-concentration region 6 can be ensured.

Moreover, in silicon carbide substrate 20 above, transmittance of light having a wavelength not shorter than 450 nm and not longer than 500 nm per unit thickness in high-nitrogen-concentration region 6 may be lower than transmittance of light having a wavelength not shorter than 450 nm and not longer than 500 nm per unit thickness in the portion other than the high-nitrogen-concentration region (low-nitrogen-concentration region 7). Transmittance above in high-nitrogen-concentration region 6 may be lower by at least 5% than transmittance in the portion other than the high-nitrogen-concentration region (low-nitrogen-concentration region 7).

In this case, high-nitrogen-concentration region 6 and low-nitrogen-concentration region 7 can readily be distinguished from each other based on a transmittance of light. Therefore, such an operation as formation of a device in a manner avoiding low-nitrogen-concentration region 7 in forming a device on the surface of silicon carbide substrate 20 (or in a manner not extending over a boundary portion between high-nitrogen-concentration region 6 and other regions) can readily be performed.

In silicon carbide substrate 20 above, micropipe density in high-nitrogen-concentration region 6 may be higher than micropipe density in the portion other than the high-nitrogen-concentration region (low-nitrogen-concentration region 7). In addition, in silicon carbide substrate 20 above, micropipe density in high-nitrogen-concentration region 6 may be at least 1.2 times as high as micropipe density in the portion other than the high-nitrogen-concentration region (low-nitrogen-concentration region 7).

In this case, since the most part of silicon carbide substrate 20 is formed from high-nitrogen-concentration region 6, micropipe density in silicon carbide substrate 20 as a whole can be made substantially uniform. Therefore, variation in ratio of occurrence of defects due to local fluctuation in micropipe density can be suppressed.

In silicon carbide substrate 20 above, variation from an average value of nitrogen concentration may be not more than 10%. In this case, since variation in nitrogen concentration is sufficiently less to such an extent as not adversely affecting characteristics of the silicon carbide substrate, silicon carbide substrate 20 uniform in characteristics can reliably be obtained.

In silicon carbide substrate 20 above, variation from an average value of dislocation density may be not more than 80%. In addition, variation from an average value of dislocation density in high-nitrogen-concentration region 6 may be not more than 80%. In this case, with variation in dislocation density as above, variation in characteristics in the main surface of silicon carbide substrate 20 can be suppressed to such an extent that no practical problem arises.

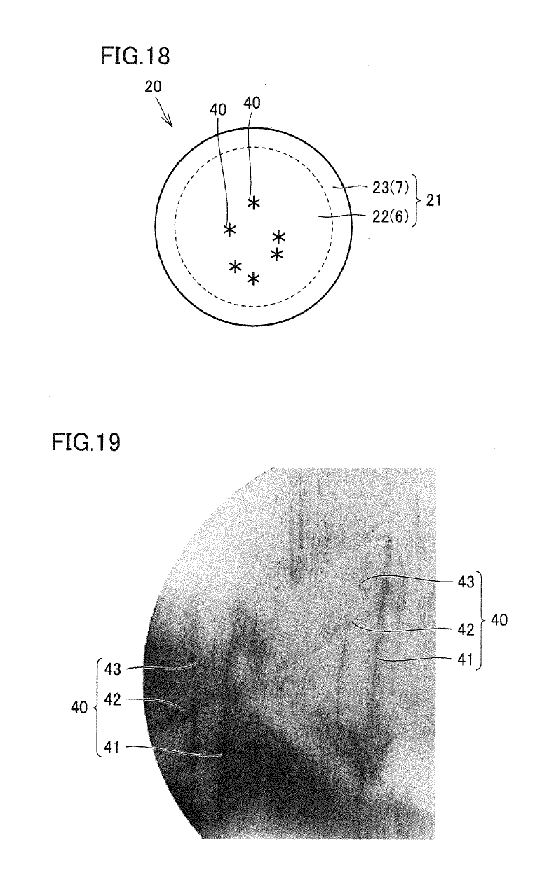

Referring to FIGS. 18 and 19, on one main surface 21 of silicon carbide substrate 20, a facet plane 22 including the substrate central portion (high-nitrogen-concentration region 6) and a non-facet plane 23 (low-nitrogen-concentration region 7) may be formed. Then, in facet plane 22 of main surface 21, a crossing pattern 40 formed by crossing of straight lines 41, 42, 43 along the <11-20> direction with one another may be present. Crossing pattern 40 can be observed with X-ray topography, and screw dislocation or micropipe is present in its central portion (a point where straight lines 41, 42, 43 cross). Though crossing pattern 40 can be observed in silicon carbide substrate 20 having 4H poly type, it is difficult to observe a crossing pattern, for example, in a 6H-type silicon carbide substrate.

By doing so, on one main surface 21 of silicon carbide substrate 20, facet plane 22 where crossing pattern 40 is present and non-facet plane 23 where crossing pattern 40 is not present can more readily be distinguished with X-ray topography. In addition, as described above, variation in characteristics of a device may take place between facet plane 22 and non-facet plane 23. Therefore, by distinguishing between facet plane 22 and non-facet plane 23 based on presence/absence of crossing pattern 40, yield analysis or the like in forming a device on silicon carbide substrate 20 is facilitated.

In addition, in silicon carbide substrate 20, number density of crossing pattern 40 in one main surface 21 may be not less than 0.1/cm² and not more than 1/cm². When number density of crossing pattern 40 exceeds 1/cm², yield of a device formed on silicon carbide substrate 20 lowers. On the other hand, when number density of crossing pattern 40 is less than 0.1/cm², a poly type of silicon carbide substrate 20 becomes unstable. For such a reason, number density of crossing pattern 40 is preferably not less than 0.1/cm² and not more than 1/cm². Furthermore, for a similar reason, number density of crossing pattern 40 is more preferably not less than 0.1/cm² and not more than 0.7/cm² and further preferably not less than 0.1/cm² and not more than 0.5/cm².

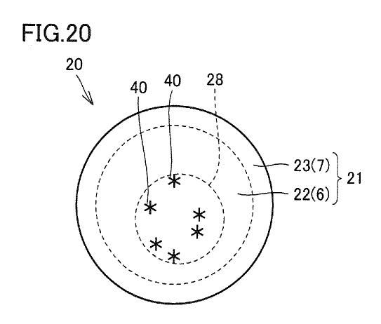

Referring to FIG. 20, in silicon carbide substrate 20, an area of a circumcircle surrounding entire crossing pattern 40 present on one main surface 21 and coming in contact with an outermost portion of at least one crossing pattern 40 (hereinafter referred to as a “virtual facet plane 28”) may be not more than 90% of an area of entire one main surface 21. Here, virtual facet plane 28 can be defined by a perfect circle in contact with an outermost portion of each of two crossing patterns 40 present at a greatest distance on main surface 21 of silicon carbide substrate 20. When the area of virtual facet plane 28 exceeds 90% of the area of entire main surface 21, crossing patterns 40 are scattered on substantially entire main surface 21, and hence yield of a device formed on silicon carbide substrate 20 lowers. For such a reason, the area of virtual facet plane 28 is preferably not more than 90% of the area of entire main surface 21. In addition, the area of virtual facet plane 28 is more preferably not less than 10% and not more than 90%, further preferably not less than 10% and not more than 75%, and still further preferably not less than 10% and not more than 50%, of the area of entire main surface 21.

As described above, according to the method of manufacturing a silicon carbide ingot in the present invention, a large facet can be formed in the central portion of silicon carbide ingot 10. In this case, substrate 20 having its entire surface as a facet can be obtained by slicing ingot 10 by grinding the outer peripheral portion of ingot 10. Here, a facet and a region other than the facet are different from each other in amount of nitrogen for doping or in dominant dislocation. In the case where a size of substrate 20 is smaller than 4 inches, influence by such difference is not great. When a substrate size is equal to or greater than 4 inches, however, influence by such difference is reinforced. Therefore, an effect of the present invention is particularly noticeable.

In addition, in the case where substrate 20 is subjected to a polishing step, for example, an amount of nitrogen with which a silicon carbide substrate is doped affects a CMP polishing rate. Therefore, an amount of nitrogen with which substrate 20 is doped is preferably uniform. When a substrate size is equal to or greater than 4 inches, warp or TTV of substrate 20 increases with increase in substrate size. In addition, influence by an amount of nitrogen for doping also becomes significant. Namely, as variation in amount of nitrogen for doping in the substrate surface is less, variation in internal stress distribution due to such an impurity as nitrogen becomes less and hence warp or TTV improves.

The amount of nitrogen for doping described above or the like also affects the step of forming a device (for example, a heat treatment step). Namely, difference in amount of nitrogen for doping will change absorptance of light in a substrate, and therefore, when the substrate is heated, local temperature difference is caused. In the case where a size of substrate 20 is small, influence by the temperature difference is not great owing to a heat conduction effect. In the case where a substrate has a large diameter such as a size not smaller than 4 inches, however, as a temperature is higher, a heat conduction effect becomes less and hence temperature distribution is more likely in silicon carbide substrate 20. Consequently, since a temperature condition varies in the substrate surface, such a problem as failure in forming a uniform film at the surface of the substrate arises. In a substrate obtained from silicon carbide ingot 10 according to the present invention, however, since uniformity in amount of nitrogen for doping is high, occurrence of such a problem as above can be suppressed.

It is noted that an amount of nitrogen for doping (nitrogen concentration) described above can be measured with SIMS. For example, in ingot 10 composed of silicon carbide according to the present invention, nitrogen concentration in a portion where an amount of nitrogen for doping is high is at least 1.5 times as high as nitrogen concentration in other regions.

With regard to substrate 20 cut from ingot 10 according to the present invention, transmittance of light having a wavelength not shorter than 400 nm and not longer than 500 nm preferably satisfies a condition as below, when silicon carbide substrate 20 has a thickness of 400 μm. Namely, when transmittance of light is measured at a plurality of locations in silicon carbide substrate 20 (for example, 10 locations including the central portion) with the use of a visible light spectroscope, average transmittance is preferably not less than 20% and not more than 65%. In addition, in a most part of the main surface of the substrate (a region occupying 70% or more in area ratio), local transmittance with respect to the average transmittance is preferably within ±20% of the average transmittance. Moreover, an index of refraction of substrate 20 is preferably not lower than 2.5 and not higher than 2.8.

With regard to dislocation density in the substrate above, dislocation was visualized and measured by treating the substrate surface with etching using molten salt KOH as an etchant. Specifically, molten salt KOH is heated to 500° C. and substrate 20 is immersed in a molten salt KOH solution approximately for 1 to 10 minutes. Consequently, pits are formed in the surface of substrate 20, in correspondence with presence of dislocations. Then, the number of pits was counted by using a Nomarski differential interference microscope and the number of pits was divided by an area of a measurement area, to thereby calculate the number of pits per unit area (that is, the number of dislocations per unit area).

Here, when dislocation density in base substrate 1 is such that micropipe density (MPD) is from 10 to 100/cm⁻² and etch pit density (EPD) is from 1 to 5E4 cm⁻², the number of dislocations is measured in substrate 20 obtained by slicing ingot 10 according to the present invention at a position at a distance of 20 mm from base substrate 1. Then, micropipe density and etch pit density decrease approximately to ½ to 1/20 with respect to base substrate 1.

### EXAMPLE

In order to confirm an effect of the present invention, an ingot and a substrate were manufactured and characteristics were measured with a method as below.

### Sample

Samples in Examples and Comparative Examples according to the present invention, of a silicon carbide ingot and a silicon carbide substrate obtained by slicing the silicon carbide ingot, were prepared as below.

### Base Substrate for Sample in Example According to the Present Invention

In order to manufacture a silicon carbide ingot, a silicon carbide single crystal substrate satisfying conditions as below was prepared as a base substrate. Specifically, in order to manufacture an ingot according to the present invention, 3 SiC single crystal substrates of 4H type were prepared as base substrates 1. Base substrate 1 can have a range of a diameter from 50 to 180 mm and a range of thickness from 100 to 2000 μm. Here, a thickness of base substrate 1 was set to 800 μm. In addition, an off angle of the main surface of base substrate 1 in a <11-20> direction with respect to the (0001) plane was set to 0.5°. With regard to the surface of base substrate 1, at least a surface on which crystal was to be grown was mirror polished. With regard to dislocation density in base substrate 1, micropipe density (MPD) was from 10 to 100/cm² and etch pit density (EPD) was from 1 to 5E4 cm⁻². It is noted that such dislocation density was measured as follows. Namely, base substrate 1 was immersed in KOH, which had been molten by being heated to 500° C., for 1 to 10 minutes and thereafter the surface of the base substrate was observed with a Nomarski differential interference microscope, to thereby count the number of pits. Then, the number of pits per unit area was calculated from an area of the observed region and the count.

### Base Substrate for Sample in Comparative Example According to the Present Invention

In order to manufacture a silicon carbide ingot according to Comparative Example, a silicon carbide single crystal substrate satisfying conditions as below was prepared as a base substrate. Specifically, 3 SiC single crystal substrates of 4H type were prepared as base substrates 1. Base substrate 1 can have a range of a diameter from 50 to 180 mm and a range of thickness from 100 to 2000 μm. Here, a thickness of base substrate 1 was set to 800 μm. In addition, an off angle of the main surface of base substrate 1 in the <11-20> direction with respect to the (0001) plane was set to 10°. With regard to the surface of base substrate 1, at least a surface on which crystal was to be grown was mirror polished as in the base substrate for Example described above. With regard to dislocation density in base substrate 1, micropipe density (MPD) was from 10 to 100/cm⁻² and etch pit density (EPD) was from 1 to 5E4 cm⁻². It is noted that a method of measuring such dislocation density is the same as the method of measuring dislocation density in the base substrate for Example described above.

### Experiment Method

### Manufacturing of Ingot

### Ingot According to Example

A silicon carbide epitaxial layer was formed on the surface of the base substrate for Example described above, to thereby manufacture a silicon carbide ingot according to Example. Specifically, base substrate 1 and powdery SiC serving as a source material were introduced in a crucible made of graphite. A distance between the source material and the base substrate was set in a range from 10 mm to 100 mm. With regard to a growth method, manufacturing is carried out generally with a method called a sublimation method or an improved Raleigh method. Specifically, this crucible was set in the inside of a heating furnace and a temperature was increased. During temperature increase, a pressure of an atmosphere was set in a range from 50 kPa to an atmospheric pressure. A temperature during crystal growth was set such that a temperature in a lower portion of the crucible was not lower than 2200° C. and not higher than 2500° C. and a temperature in an upper portion of the crucible was not lower than 2000° C. and not higher than 2350° C. A temperature in the lower portion of the crucible was set higher than the temperature in the upper portion of the crucible. It is noted that the pressure of the atmosphere was controlled in a range from 0.1 to 20 kPa after temperature increase to a temperature during crystal growth. In addition, any one of He, Ar, and N₂ or a gas mixture composed of a plurality thereof was employed as an atmospheric gas. It is noted that an Ar+N₂ gas was employed as an atmospheric gas here. During cooling, initially, the pressure of the atmosphere was increased to a range from 50 kPa to the atmospheric pressure and then the temperature of the heating furnace was lowered.

In addition, during crystal growth described above, ingot 10 was grown such that a temperature gradient in a direction of width when viewed in a direction of growth at the outermost growth surface of ingot 10 grown on the surface of base substrate 1 (the surface opposite to the side where base substrate 1 was located in ingot 10 in FIG. 7 or the surface of ingot 10 opposed to a direction of supply of a source gas shown with an arrow 13 in FIG. 7) was not more than 10° C./cm. Specifically, as described with reference to FIG. 7, with a temperature of central portion 24 of ingot 10 in FIG. 7 being denoted as Ta, a temperature of end portion 27 being denoted as Tb, and a temperature of outermost peripheral portion 16 as Tc, crystal was grown such that the relational expression of Tc>Tb≧Ta was satisfied and temperature Tb and temperature Ta satisfied relation of the temperature gradient ((absolute value of difference between temperature Ta and temperature Tb)/(distance between central portion 24 and end portion 27)) not more than 10° C./cm. Specifically, a felt serving as a heat insulating member was arranged on the upper surface side of the crucible. Such an ingot that silicon carbide was grown on the base substrate with this method was taken out.

### Ingot According to Comparative Example

A silicon carbide ingot according to Comparative Example was manufactured by forming a silicon carbide epitaxial layer on the surface of a base substrate for Comparative Example. Here, an ingot according to Comparative Example was manufactured basically with a method the same as the method of manufacturing an ingot according to Example described above. The ingot according to Comparative Example where silicon carbide was thus grown was taken out.

### Measurement of Planarity of Outermost Surface of Ingot

Planarity of the surface of the ingot according to Example and Comparative Example described above was measured. Planarity of the ingot was found by measuring a height of the ingot (a distance from the surface of the base substrate to the surface of the ingot) in the region (in the central portion) excluding a range of 10% of a diameter of the ingot on the outer peripheral side, with respect to the diameter of the ingot. It is noted that, though height distribution over the entire surface of the ingot is preferably taken, only measurement of a height of the ingot at 1- to 5-mm pitches in a direction of cross from the center of the ingot will suffice.

In the case of measurement in a direction of cross as such, planarity is measured as follows. Namely, the height of the surface of ingot 10 is measured at a plurality of positions (measurement points) arranged in the direction of cross at 5-mm pitches from the center of the surface of the ingot (preferably, in matrix at 5-mm pitches). Then, difference in height between adjacent measurement points is calculated. In addition, an angle corresponding to inclination of the surface of the ingot (inclination angle) between the adjacent measurement points is found from a tangent (tan) which can be determined by difference in height and a distance between measurement points.

### Manufacturing of Substrate

After measurement of a surface shape was conducted as above, the ingot according to Example and Comparative Example described above was formed in a columnar shape. Then, a silicon carbide substrate was manufactured by slicing the ingot in a direction along the surface of the base substrate, with the use of a wire saw. A thickness of the substrate was set to 400 μm to 500 μm. In addition, after slicing, opposing surfaces of the silicon carbide substrate were subjected to mirror polishing treatment. Consequently, the thickness of the silicon carbide substrate was in a range from 350 μm to 420 μm.

### Measurement of Nitrogen Concentration

In the fabricated substrate, nitrogen concentration was measured in a region relatively high in nitrogen concentration (high-nitrogen-concentration region), which was the region located under the (0001) facet plane of the ingot, and in other regions. SIMS (secondary ion mass spectrometry) was employed as a measurement method. It is noted that a measurement thickness was set to 10 μm in order to suppress variation in measurement.

### Measurement of Transmittance

With regard to the fabricated substrate, transmittance of light was measured in the high-nitrogen-concentration region and in other regions. With regard to a measurement method, transmittance of light in a wavelength range from 400 nm to 500 nm was measured with the use of a visible light spectroscope.

### Measurement of Dislocation Density

With regard to the fabricated substrate, dislocation density at the surface was measured. Specifically, a method as below was employed. Initially, the silicon carbide substrate was immersed in the molten salt KOH solution heated to 500° C., for 1 to 10 minutes. Thereafter, the surface of the silicon carbide substrate was observed with a Nomarski differential interference microscope and the number of pits formed was counted. Regarding count, it is preferred to take a whole surface mapping photograph, thereafter count the total number of pits, and then calculate average density per unit area. For example, however, in the case of a silicon carbide substrate having a diameter of 2 inches, average density of pits at 5 or more measurement locations may be defined as pit density in such a manner that the number of pits per unit area is counted at 5 points in total including the central portion of the substrate and positions each at a distance of approximately 18 mm therefrom in the direction of cross and then average thereof is calculated. As a silicon carbide substrate to be evaluated, a substrate at a position distant by 20 mm from the outermost surface of the base substrate of the fabricated ingot was selected for comparison with data of the base substrate.

### Results

### As to Ingot

In the ingot according to Example, the (0001) facet plane was arranged in a wide region including the central portion of the outermost surface. A width of the (0001) facet plane in a plan view was 140 mm when the ingot had a diameter of 163 mm, it was 95 mm when the ingot had a diameter of 115 mm, and it was 52 mm when the ingot had a diameter of 63 mm. An average value of the ingot height was also 35 mm when the ingot had a diameter of 163 mm, it was 33 mm when the ingot had a diameter of 115 mm, and it was 36 mm when the ingot had a diameter of 63 mm. Then, an inclination angle indicating planarity of the surface was each not greater than 10° on average and sufficient planarity was achieved.

On the other hand, in the ingot according to Comparative Example, the (0001) facet plane relatively small in area was created in the central portion of the outermost surface of the ingot. A width of the (0001) facet plane was in a range from 12% to 45% of the ingot diameter. In addition, an inclination angle indicating planarity of the surface exceeded 10° on average.

### As to Substrate

In the substrate cut from the ingot according to Example, a high-nitrogen-concentration region relatively high in nitrogen concentration was formed in a region located under the (0001) facet plane (a region located at a central portion of the substrate). The high-nitrogen-concentration region arranged substantially matched with the position of the facet. In addition, a width of the high-nitrogen-concentration region was generally within a range of 80% of the ingot diameter, although there was distribution in a direction of height of the ingot.

Meanwhile, in the substrate cut from the ingot according to Comparative Example as well, a high-nitrogen-concentration region was formed in a region located under the (0001) facet plane. The high-nitrogen-concentration region in Comparative Example also substantially matched with the position of the facet. In addition, distribution of sizes of the high-nitrogen-concentration regions was present in the direction of height of the ingot and a width of the high-nitrogen-concentration region was in a range from 5 to 45% of the ingot diameter. Though there was a portion where a width (size) of the high concentration region was not more than 10% of the ingot diameter also in Comparative Example, this was a region distant by not more than 5 mm from a surface position of the base substrate. This is because a total amount of growth of silicon carbide is still small in that range and hence planarity at the surface of grown silicon carbide is relatively kept, which is a result different from that in Example where planarity is always kept during crystal growth.

### As to Nitrogen Concentration

In the substrate according to Example, nitrogen concentration in the high-nitrogen-concentration region was 1.2E19 cm⁻³ and nitrogen concentration in other regions was from 8E18 to 1E19 cm⁻³. In addition, nitrogen concentration at any 5 points in the region other than the high-nitrogen-concentration region was within a range of 20% from average concentration at 5 points.

In the substrate according to Comparative Example, nitrogen concentration in the high-nitrogen-concentration region was 1.2E19 cm⁻³ and nitrogen concentration in other regions was from 8E18 to 1E19 cm⁻³.

### As to Transmittance

In the substrates according to Example and Comparative Example, transmittance of light having a wavelength from 400 to 500 nm was 10 to 20% in the high-nitrogen-concentration region. Meanwhile, the transmittance was from 25 to 35% in other regions in the substrate. In the silicon carbide substrate cut from the ingot lightly doped with nitrogen, which was different from the present experiment, transmittance in the high-nitrogen-concentration region was from 35 to 45% and transmittance in other regions was from 45 to 65%. An index of refraction of the silicon carbide substrate obtained by calculation based on wavelength characteristics of transmittance was from 2.5 to 2.8.

### As to Dislocation Density

Measurement was conducted with regard to a substrate obtained by slicing the ingot at a position distant by 20 mm from the base substrate. Here, when micropipe density (MPD) was from 10 to 100/cm² and etch pit density (EPD) was from 1 to 5E4 cm⁻² with regard to dislocation density in the base substrate, in the substrate according to Example, in a region other than the high-nitrogen-concentration region, both of MPD and EPD could be lowered to ½ to 1/20 with respect to the base substrate.

On the other hand, in the case of the substrate according to Comparative Example, though there was a substrate of which MPD and EPD lowered to ½ to 2.5 with respect to the base substrate, there was also a case of increase on the contrary.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a silicon carbide ingot, comprising the steps of:
preparing a base substrate having an off angle with respect to a (0001) plane not greater than 1° and composed of single crystal silicon carbide; and
growing a silicon carbide layer on a surface of said base substrate,
in said step of growing a silicon carbide layer, a temperature gradient in a direction of width when viewed in a direction of growth of said silicon carbide layer being set to 10° C./cm or less.

2. The method of manufacturing a silicon carbide ingot according to claim 1, wherein
a surface of said silicon carbide layer located opposite to a side where the base substrate is located includes a (0001) facet plane, and
said (0001) facet plane includes a central portion of said surface of the silicon carbide layer.

3. The method of manufacturing a silicon carbide ingot according to claim 2, wherein
a portion located under a region having said (0001) facet plane in said silicon carbide layer after the step of growing a silicon carbide layer is a high-nitrogen-concentration region higher in nitrogen concentration than a portion other than said portion located under the region having said (0001) facet plane in said silicon carbide layer.

4. The method of manufacturing a silicon carbide ingot according to claim 3, further comprising the step of removing a portion other than said high-nitrogen-concentration region in said silicon carbide layer.

5. The method of manufacturing a silicon carbide ingot according to claim 3, wherein
transmittance of light having a wavelength not shorter than 450 nm and not longer than 500 nm per unit thickness in said high-nitrogen-concentration region is lower than said transmittance of light per unit thickness in the portion other than said high-nitrogen-concentration region in said silicon carbide layer.

6. The method of manufacturing a silicon carbide ingot according to claim 2, wherein
micropipe density of a portion located under a region having said (0001) facet plane is higher than micropipe density in a portion other than said portion located under the region having said (0001) facet plane in said silicon carbide layer.

7. A method of manufacturing a silicon carbide substrate, comprising the steps of:
preparing a silicon carbide ingot with the method of manufacturing a silicon carbide ingot according to claim 1,
a surface of said silicon carbide layer located opposite to a side where the base substrate is located including a (0001) facet plane,
said (0001) facet plane including a central portion of said surface of the silicon carbide layer,
in said step of preparing a silicon carbide ingot, a portion located under a region having said (0001) facet plane in said silicon carbide layer after the step of growing a silicon carbide layer being a high-nitrogen-concentration region higher in nitrogen concentration than a portion other than said portion located under the region having said (0001) facet plane in said silicon carbide layer;
removing a portion other than said high-nitrogen-concentration region from said silicon carbide ingot; and
slicing said silicon carbide ingot after said step of removing a portion other than said high-nitrogen-concentration region.

8. A silicon carbide ingot, comprising:
a base substrate having an off angle with respect to a (0001) plane not greater than 1° and composed of single crystal silicon carbide; and
a silicon carbide layer formed on a surface of said base substrate,
a surface of said silicon carbide layer located opposite to a side where said base substrate is located including a (0001) facet plane, and
said (0001) facet plane including a central portion of the surface of said silicon carbide layer and extending from said central portion to a position at a distance of 10% of a width of said surface from an outer peripheral end of said surface.

9. The silicon carbide ingot according to claim 8, wherein
a portion located under a region having said (0001) facet plane in said silicon carbide layer is a high-nitrogen-concentration region higher in nitrogen concentration than a portion other than said portion located under the region having said (0001) facet plane in said silicon carbide layer.

10. The silicon carbide ingot according to claim 9, wherein
transmittance of light having a wavelength not shorter than 450 nm and not longer than 500 nm per unit thickness in said high-nitrogen-concentration region is lower than said transmittance of light per unit thickness in the portion other than said high-nitrogen-concentration region in said silicon carbide layer.

11. The silicon carbide ingot according to claim 8, wherein
micropipe density of the portion located under the region having said (0001) facet plane is higher than micropipe density in the portion other than said portion located under the region having said (0001) facet plane in said silicon carbide layer.

12. A silicon carbide substrate, obtained by slicing the silicon carbide ingot according to claim 8.

13. The silicon carbide substrate according to claim 12, wherein
on at least one main surface, a pattern which is formed by crossing of a straight line along a <11-20> direction and can be observed with X-ray topography is present.

14. The silicon carbide substrate according to claim 13, wherein
number density of said pattern present on said one main surface is not less than 0.1/cm² and not more than 1/cm².

15. A silicon carbide substrate, wherein
on at least one main surface, a pattern which is formed by crossing of a straight line along a <11-20> direction and can be observed with X-ray topography is present, and
number density of said pattern present on said one main surface is not less than 0.1/cm² and not more than 1/cm².

16. The silicon carbide substrate according to claim 15, wherein
an area of a circumcircle surrounding entire said pattern present on said one main surface and coming in contact with an outermost portion of at least one said pattern is not more than 90% of an area of entire said one main surface.
